(19) United States
(12) Patent Application Publication
(10) Pub. No.: US 2013/0125392 A1
(43) Pub. Date: May 23, 2013

(54) Mounting of Components Using Solder Paste Fiducials

(71) Applicants: Dennis R. Pyper, San Jose, CA (US); Hong Wang, Shenzhen (CN); Wyeman Chen, Fremont, CA (US)

(72) Inventors: Dennis R. Pyper, San Jose, CA (US); Hong Wang, Shenzhen (CN); Wyeman Chen, Fremont, CA (US)

(21) Appl. No.: 13/298,818

(22) Filed: Nov. 17, 2011

(51) Int. Cl. H05K 3/30

(52) U.S. Cl. 29/834

(57) ABSTRACT

A printed circuit board may have patterned traces. Components may be mounted to the printed circuit board using solder. Solder paste may be printed onto the printed circuit board using a stencil. Following reflow operations, the solder paste may form solder bumps that connect component leads to traces on the printed circuit board. Misalignment between the mounted components and printed circuit board traces can be minimized by forming fiducials from solder paste. During the process of printing solder paste patterns on the printed circuit board, solder paste printing equipment may form the solder paste fiducials. Component mounting equipment may use cameras or other imaging equipment to gather information on the location of the solder paste fiducials. The component mounting equipment may then mount the components on the printed circuit using the information on the location of the solder paste fiducials.

### BACKGROUND

This relates to electronic components and, more particularly, to mounting electronic components onto substrates such as printed circuit boards.

Components such as integrated circuits and other electronic devices are typically mounted on printed circuit board substrates using solder. In a typical arrangement, a printed circuit board is provided with patterned traces. Solder paste is printed onto the surface of the printed circuit board using a stencil. A surface mount tool may then attach components to the board using solder bumps formed from the printed solder paste.

Conventional arrangements for mounting components on a printed circuit board use machine vision equipment to ascertain the position of the printed circuit board. A printed circuit board may be provided with patterned metal structures called fiducials. The locations of the fiducials can be recognized by the machine vision equipment. The machine vision equipment may then use the known locations of the fiducials to print solder paste onto the surface of the printed circuit board. During subsequent pick-and-place operations, components can be mounted to the board using solder bumps formed from the solder paste.

A pick-and-place tool generally includes machine vision equipment. The machine vision equipment in the pick-and-place tool may likewise be used to ascertain the position of the printed circuit board by acquiring images of the printed circuit fiducials. Components may then be mounted to the printed circuit board in alignment with the printed circuit fiducials.

If care is not taken, this type of assembly process may produce faulty boards. In particular, because the pick-and-place tool does not directly measure the locations of the solder paste patterns on the printed circuit board, the pick-and-place tool may potentially mount components to the board in positions in which leads on the components are misaligned relative to the solder paste. Misalignment tolerance can be enhanced by increasing feature size. However, the use of large features may not be acceptable, particularly in applications in which compact printed circuit layouts are needed. Another way to minimize the potential for misalignment involves reducing printed circuit board panel size, but such panel size reductions may adversely affect throughput.

It would therefore be desirable to be able to provide improved techniques for mounting electronic components to printed circuits.

### SUMMARY

A printed circuit board may have patterned traces. Components may be mounted to the printed circuit board using solder. Solder paste may be printed onto the printed circuit board using a stencil. Following reflow operations, the solder paste may form solder bumps that connect component leads to traces on the printed circuit board.

Misalignment between the mounted components and printed circuit board traces can be minimized by forming fiducials from the solder paste and using the solder paste fiducials for alignment during component mounting operations.

During the process of printing solder paste patterns on the printed circuit board, solder paste printing equipment may form the solder paste fiducials. Component mounting equipment may use cameras or other imaging equipment to capture images of the printed solder paste fiducials. The component mounting equipment may then mount components in alignment with the solder paste fiducials. Because the potential for misalignment between components and solder paste patterns can be minimized when the component mounting equipment mounts components in alignment with the solder paste, the components and solder paste patterns may be mounted within allowable misalignment tolerances. Following reflow operations, surface tension from molten solder may help bring the components into alignment with printed circuit board traces on the printed circuit board.

Further features of the invention, its nature and various advantages will be more apparent from the accompanying drawings and the following detailed description of the preferred embodiments.

### BRIEF DESCRIPTION OF THE DRAWINGS

FIG. 1 is a diagram of an illustrative system for printing solder paste patterns including solder paste fiducials on a printed circuit substrate in accordance with an embodiment of the present invention.

FIG. 2 is a diagram of an illustrative system for mounting components onto a printed circuit substrate in accordance with an embodiment of the present invention.

FIG. 3 is a top view of an illustrative circular printed solder paste fiducial in accordance with an embodiment of the present invention.

FIG. 4 is a top view of an illustrative square printed solder paste fiducial in accordance with an embodiment of the present invention.

FIG. 5 is a top view of an illustrative cross-shaped printed solder paste fiducial in accordance with an embodiment of the present invention.

FIG. 6 is a top view of an illustrative solder paste fiducial that has been printed on an underlying patterned metal pad on a printed circuit board in accordance with an embodiment of the present invention.

FIG. 7 is a cross-sectional side view of an illustrative component that is about to be mounted to a printed solder paste feature in accordance with an embodiment of the present invention.

FIG. 8 is a cross-sectional side view of the illustrative component of FIG. 7 following reflowing of the solder paste showing how the solder reflow process may allow the component to become centered over a contact pad trace on a printed circuit in accordance with an embodiment of the present invention.

FIG. 9 is a flow chart of illustrative steps involved in mounting components to a printed circuit board using solder paste printing equipment of the type shown in FIG. 1 and component mounting equipment of the type shown in FIG. 2 in accordance with an embodiment of the present invention.

### DETAILED DESCRIPTION

Traditional component mounting techniques involve the formation of solder paste features on a printed circuit board. Fiducials on the printed circuit board are used to ensure proper alignment of the solder paste features with underlying metal traces on the printed circuit board. The fiducials on the printed circuit board are also used to align components with respect to the board during subsequent component mounting operations.

Due to manufacturing variations, printed solder paste features on a board are generally not in perfect alignment with the underlying metal traces on the board. As a result, there is a potential for component leads to be misaligned with respect to solder paste features when components are mounted to the board in alignment with the printed circuit fiducials

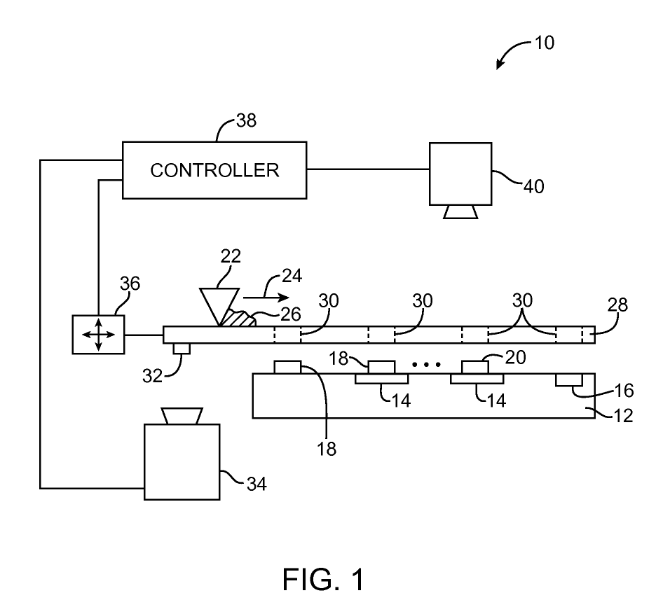

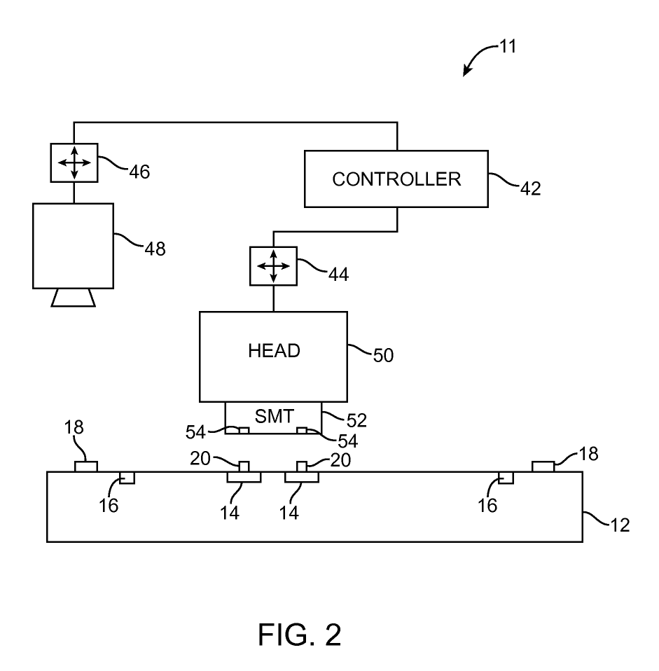

These shortcomings of conventional manufacturing techniques can be addressed using equipment of the type shown in FIGS. 1 and 2. Using equipment such as the equipment of FIGS. 1 and 2, the potential for component misalignment failures can be reduced.

To minimize or eliminate the potential for misalignment failures, fiducials may be incorporated into a printed solder paste layer as part of the process of printing solder paste features on a printed circuit with equipment of the type shown in FIG. 1. During subsequent component placement operations using equipment of the type shown in FIG. 2, components may be aligned with respect to the printed solder paste fiducials instead of the printed circuit fiducials. Because component alignment is performed with respect to the solder paste fiducials, the potential for misalignment between component leads and solder paste features may be reduced and the potential for misalignment failures due to component leads being improperly soldered to traces on the printed circuit board may be reduced.

The diagram of FIG. 1 shows illustrative equipment that may be used for printing solder paste fiducials. As shown in FIG. 1, equipment 10 may include a controller such as controller 38. Controller 38 may be based on one or more computers or other processing equipment. During operation, computing equipment in controller 38 may gather digital images using cameras such as cameras 40 and 34. There may be any suitable number of cameras in equipment 10. In the example of FIG. 1, there are two cameras in equipment 10. This is merely illustrative. Equipment 10 may include one or more cameras, two or more cameras, three or more cameras, or any other suitable number of cameras.

Equipment 10 may be used to print solder paste onto printed circuit 12. Equipment 10 may, for example, include a solder paste printing stencil such as stainless steel stencil 28. Squeegee 22 may be moved in direction 24 to force solder paste 26 (e.g., tin-based solder paste) through a pattern of openings 30 in stencil 28, thereby printing solder paste onto the surface of printed circuit 12.

Printed circuit 12, which may sometimes be referred to as a printed circuit substrate or printed circuit board, may be formed from a rigid printed circuit board material (e.g., fiberglass-filled epoxy), a flexible printed circuit board material (e.g., a flexible sheet of polymer such as a sheet of polyimide), or other dielectric materials.

As shown in FIG. 1, printed circuit 12 may include patterned conductive structures such as patterned features (traces) 14 and 16. Features 14 and 16 may be formed from copper (e.g., gold plated copper), other metals, or other conductive materials. Features 14 and 16 may include pads, vias, interconnect lines, and other patterned conductive structures. Printed circuit board 12 may include multiple layers of interconnects and other conductive structures. The features shown in FIG. 1 are located on the upper surface of printed circuit board 12.

To facilitate alignment between stencil 28 and printed circuit board 12, printed circuit board 12 may include one or more fiducials such as fiducial 16. Fiducials, which are sometimes referred to as alignment or registration features (or marks) may be formed from a patterned portion of the same metal that is used in forming traces 14.

During solder paste printing, solder paste 26 may be printed on the surface of printed circuit 12 using solder paste printing equipment 10. In particular, squeegee 22 may be moved in direction 24 to force solder paste 26 through openings 30 in stencil 28 so that solder paste forms solder paste features such as solder paste features 18 and 20. Some of the solder paste features that are printed on printed circuit 12 such as feature 20 in the example of FIG. 1 may be subsequently used to form solder bump attachment structures that attach component leads to associated traces 14. Other solder paste features such as illustrative solder paste structures 18 of FIG. 1 may serve as solder paste fiducials. Solder paste fiducials 18 may be printed on portions of printed circuit 12 that are not covered by traces (see, e.g., the left-most fiducial 18 in FIG. 1) and/or may be printed on portions of printed circuit 12 that are covered with patterned conductor (see, e.g., the second-to-left-most fiducial 18 of printed circuit 12).

Controller 38 may use information from machine vision equipment such as camera equipment 40 to determine the location of fiducial 16 (and therefore the location of printed circuit 12). To capture an image of printed circuit 12 and thereby obtain information on the location of printed circuit fiducial 16, controller 38 may use positioner 36 to move stencil 28 clear of printed circuit 12. Once controller 38 has moved stencil 28 away from printed circuit 12 so that the surface of printed circuit 12 in the vicinity of fiducials such as fiducial 16 is visible to camera 40 and is not blocked by stencil 28, controller 38 can use camera 40 to capture digital images of printed circuit 12 and printed circuit fiducials such as printed circuit fiducial 16. The digital image data from camera 40 may be processed by controller 38 to locate fiducial 16.

Controller 38 may use information from machine vision equipment such as camera equipment 34 to ascertain the location of stencil 28. For example, camera 34 may be used to acquire digital images 28 of stencil fiducial (alignment feature) 32.

The information that equipment 10 gathers from fiducial 16 may allow equipment 10 to ascertain the location of printed circuit board 12 while the information that equipment 10 gathers from fiducial 32 may allow equipment 10 to ascertain the location of stencil 28. Based on knowledge of the relative positions of printed circuit board 12 and stencil 28, equipment 10 may print solder paste features such as solder paste fiducials 18 and features 20. Solder paste fiducials 18 that are printed in this way will be aligned with respect to printed circuit fiducials such as printed circuit fiducial 16.

Following printing of solder paste fiducials 18, equipment of the type shown in FIG. 2 may be used to mount electrical components on printed circuit board 12. As shown in FIG. 2, equipment 11 may include a pick-and-place head such as head 50 (sometimes referred to as a surface mount technology mounting tool) or other component mounting equipment to mount components such as electronic component 52 to printed circuit 12. Equipment 11 may include a controller such as controller 42. Controller 42 may include one or more computers or other computing equipment. If desired, controller 42 of FIG. 2 may share resources with controller 38 of FIG. 1.

Controller 42 may control the position of head 50 using positioner 44. If desired, head 50 may include heating equipment for heating component 52 and reflowing solder paste. Solder paste reflow operations may also be performed using a reflow oven (e.g., a reflow oven in which an entire panel of printed circuit boards is heated simultaneously). Other types of heat sources for reflowing solder paste may be used if desired. These are merely illustrative examples.

As shown in FIG. 2, component 52 (e.g., an integrated circuit, switch, discrete component, or other surface mount component) may have leads (contacts) such as leads 54. Leads 54 may have the shape of pads, protruding conductive structures, or other suitable shapes. During the process of mounting component 52 to printed circuit 12, leads 54 may be soldered to patterned traces 14 on the surface of printed circuit 12 using solder bumps formed from solder paste 20.

Solder paste 20 may be formed at the same time as solder paste fiducials 18 using solder paste printing equipment such as printing equipment 10 of FIG. 1. Although some misalignment between printed solder paste features and printed circuit fiducials 16 may be introduced as a result of the solder paste printing process any such misalignment will also be reflected in the locations of printed solder paste fiducials 18. As a result, system 11 may minimize possible misaligment of components such as component 52 with respect to traces 14 by aligning components such as component 52 with respect to solder paste fiducial 18. Solder paste fiducials 18 are preferably printed at the same times as features 20 using stencil 28 (FIG. 1), so any misalignment of features 20 with respect to traces 14 will result in a corresponding shift of solder paste fiducials 18. This minimizes the amount by which components such as component 52 will be misaligned with respect to solder paste features 20 when components are placed on features 20 by mounting equipment 11.

When it is desired to mount component 52 on printed circuit 12, controller 42 may use positioner 46 to move camera 48 into the vicinity of printed circuit 12. Controller 42 may then use camera 48 to capture a digital image of the surface of printed circuit 12. The digital image data that is gathered in this way will include digital images of solder paste fiducials 18. During image processing operations implemented using controller 42, controller 42 can determine the location of solder paste fiducials 18 and can use the location of solder paste fiducials 18 to determine the location of solder paste features 20 (e.g., solder paste for forming solder bumps during subsequent reflow operations). This allows equipment 11 to mount component 52 so that leads 54 make contact with respective solder paste features 20. Because component 52 is aligned with respect to solder paste fiducial 18 rather than printed circuit board fiducial 16, misalignment between component leads 54 and solder paste features 20 may be minimized.

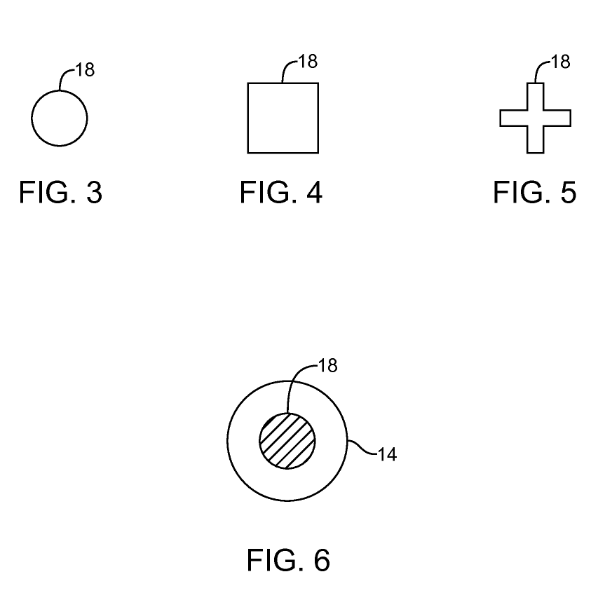

Printed solder paste fiducials 18 may have any suitable shape. A top view of an illustrative circular printed solder paste fiducial 18 is shown in FIG. 3. FIG. 4 is a top view of an illustrative rectangular printed solder paste fiducial. In the example of FIG. 5, printed solder paste fiducial 18 has been implemented using a cross shape. These are merely illustrative examples. Solder paste fiducials 18 may have straight sides, curved sides, or combinations of straight and curved sides, may be formed from one or more concentric rings, or may be formed form any other suitable pattered solder structure.

As shown in the top view of FIG. 6, printed solder paste fiducial 18 may be printed on an underlying trace 14 on printed circuit board 12 (see, e.g., FIG. 1). In the example of FIG. 6, printed solder paste fiducial 18 has the shape of a circle with a diameter that is about half the size of the diameter of an underlying circular pad 14 on printed circuit 12. Other patterns of pads 14 and solder paste fiducials may be used if desired. The arrangement of FIG. 6 is merely illustrative.

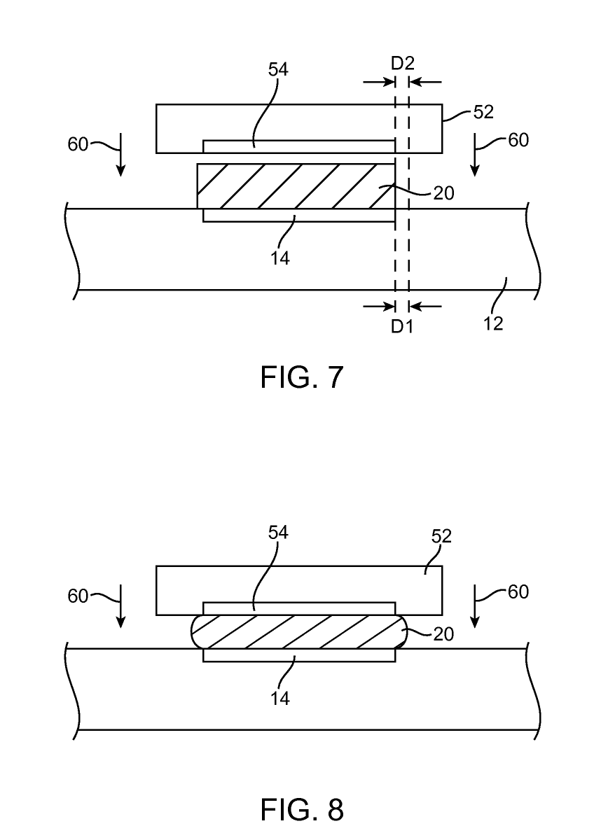

FIG. 7 is a cross-sectional side view of printed circuit board 12 following printing of a solder paste feature onto printed circuit board trace 14 and before mounting of component 52 to board 12. As shown in FIG. 7, there may be a misalignment D1 between printed solder paste feature 20 and printed circuit feature 14. When aligning component 52 for mounting on printed circuit 12 by moving component 52 downwards in direction 60, equipment 11 of FIG. 2 may align component 52 with respect to printed solder paste fiducial 18 (FIG. 2). As shown in FIG. 7, there may be misalignment D2 between component 52 (e.g., lead 54) and solder paste feature 20 when component 52 is mounted on printed circuit 12. Nevertheless, because component 52 is mounted on printed circuit 12 in alignment with printed solder paste fiducial 18, the amount of misalignment D2 between leads 54 and solder paste feature 20 can be well controlled. Because misalignment D2 is not excessive, lead 54 will be sufficiently well aligned with solder paste 20 to form a connection between the upper portions of solder paste 20 and lead 54 during reflow operations. Similarly, because misalignment D1 is not excessive, a solder connection may be formed between the lower surface of solder paste 20 and trace 14 during reflow operations. The surface tension that is produced by the molten solder (i.e., molten solder paste 20) may allow component 52 to center itself above traces 14, as shown in FIG. 8. As a result, misalignment between component 52 and printed circuit board 12 (i.e., misalignment between leads 54 and traces 14) can be minimized.

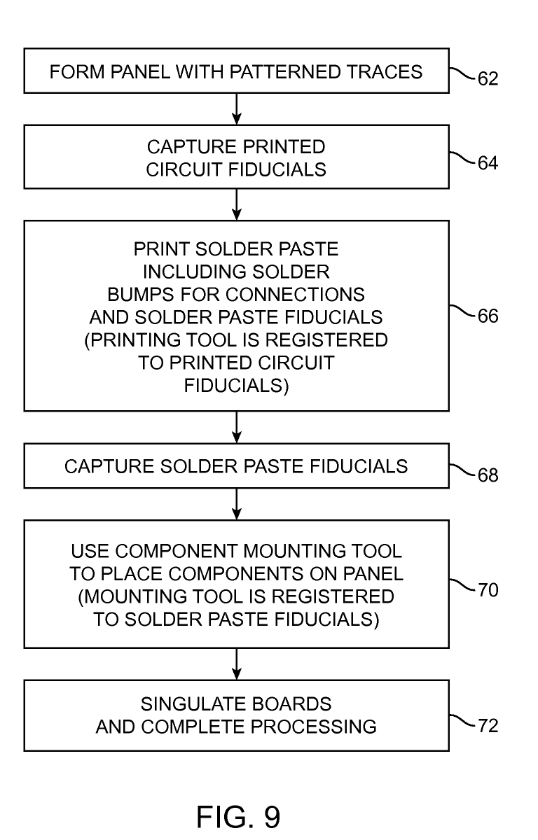

FIG. 9 is a flow chart of illustrative steps involved in mounting components 52 to printed circuit board 12 using equipment of the type shown in FIGS. 1 and 2.

At step 62, a printed circuit substrate such as a panel of printed circuit boards may be fabricated. The printed circuit board panel may contain multiple printed circuit boards held in place in a frame (i.e., a frame formed from unused printed circuit substrate material in the panel). Due to the enhanced alignment capabilities of the equipment of FIGS. 1 and 2, frame area can be minimized, packing density may be enhanced, and waste may be reduced. The printed circuit board (i.e., the panel) of step 62 may include metal traces or other conductive structures. The metal traces may be used to form interconnects, vias, contact pads, printed circuit fiducials, and other structures. The metal traces may be patterned using photolithography or other suitable patterning techniques.

At step 64, information may be gathered on the position of printed circuit fiducials. For example, digital image data indicating where printed circuit fiducials such as printed circuit fiducials 16 are located can be captured using camera equipment such as camera 40 of FIG. 1. This allows a controller such as controller 38 or other control equipment to ascertain the location of printed circuit board 12.

At step 66, equipment 10 of FIG. 1 may be used to print solder paste patterns on the surface of printed circuit board 12 in alignment with printed circuit board fiducials such as fiducials 16 using the gathered position information indicating where printed circuit fiducials 16 are located. The printed solder paste features may include solder paste pads and other features for forming solder bump connections for mounting component leads to printed circuit board traces (e.g., features 20 of FIG. 1) and may include one or more printed solder paste fiducials 18. Because the solder paste printing tool knows the location of fiducials 16, the printed solder paste features can be printed in registration (alignment) with fiducials 16.

At step 68, equipment such as equipment 11 of FIG.

2 may gather information on the position of solder paste fiducials 18. For example, equipment 11 may gather position information indicating where solder paste fiducials 18 and therefore solder paste features 20 are located by capturing images of solder paste fiducials 18 with camera 48.

At step 70, equipment 11 (e.g., a pick-and-place tool or other surface mount technology mounting equipment) may be used to place components such as component 52 on the surface of printed circuit board 12 in alignment with solder paste features 20 using the gathered position information indicating where printed solder paste fiducials 18 are located. Because the component mounting tool knows the location of solder paste fiducials 18, the component mounting tool can mount components 52 in registration (alignment) with solder paste fiducials 18 and therefore solder paste features 20.

At step 72, reflow operations may be performed to reflow solder paste 20 and form corresponding solder bumps. The solder bumps may be used to connect component leads such as leads 54 to respective printed circuit board traces 14. Following reflow operations, the printed circuit board panel may be singulated and installed in electronic equipment.

The foregoing is merely illustrative of the principles of this invention and various modifications can be made by those skilled in the art without departing from the scope and spirit of the invention.

What is claimed is:

1. A method of mounting components on a printed circuit, comprising:
printing at least one solder paste fiducial on the printed circuit; and
mounting an electrical component to the printed circuit by aligning the electrical component to the solder paste fiducial.

2. The method defined in claim 1 wherein mounting the electrical component comprises using mounting equipment to mount the electrical component to solder paste features on the printed circuit.

3. The method defined in claim 2 further comprising:
with solder paste printing equipment, printing both the solder paste features and the solder paste fiducial on the printed circuit.

4. The method defined in claim 3 wherein the mounting equipment includes a camera configured to capture an image of the solder paste fiducial to ascertain where the solder paste fiducial is located.

5. The method defined in claim 4 wherein the printed circuit includes at least one printed circuit fiducial and wherein the solder paste printing equipment is configured to capture at least one image of the printed circuit that includes the printed circuit fiducial.

6. The method defined in claim 1 wherein the printed circuit includes at least one printed circuit fiducial formed from a metal trace on the printed circuit and wherein printing the solder paste fiducial comprises printing the solder paste fiducial on the printed circuit by aligning the solder paste fiducial to the printed circuit fiducial.

7. The method defined in claim 6 wherein printing the solder paste fiducial comprises ascertaining where the printed circuit fiducial is located using a camera in solder paste printing equipment.

8. The method defined in claim 7 comprising moving a solder paste printing stencil with a positioner in the solder paste printing equipment, wherein moving the solder paste printing stencil comprises moving the solder paste printing stencil to align openings in the solder paste printing stencil with respect to the printed circuit fiducial.

9. The method defined in claim 8 wherein the printed circuit includes at least one trace and wherein printing the solder paste fiducial comprises printing the solder paste fiducial on the at least one trace.

10. The method define in claim 1 wherein the printed circuit includes at least one trace, the method further comprising:
printing a solder paste feature on the trace; and
reflowing the solder paste of the solder paste feature to solder the component to the at least one trace.

11. The method defined in claim 10 wherein the printed circuit comprises a printed circuit board in a panel of printed circuit boards, the method further comprising:
singulating the printed circuit from the panel following reflowing of the solder paste.

12. A method, comprising:
forming a printed circuit board having patterned traces including at least one printed circuit fiducial;
gathering position information indicating where the printed circuit fiducial is located; and
printing a solder paste fiducial on the printed circuit board based on the position information indicating where the printed circuit fiducial is located.

13. The method defined in claim 12 further comprising:
gathering position information indicating where the printed solder paste fiducial is located.

14. The method defined in claim 13 further comprising:
mounting an electrical component on the printed circuit based on the position information indicating where the printed solder paste fiducial is located.

15. The method defined in claim 14 wherein gathering the position information indicating where the printed solder paste fiducial is located comprises using machine vision equipment to capture digital image data.

16. The method defined in claim 14 further comprising printing solder paste features on the printed circuit while printing the solder paste fiducial, wherein mounting the electrical component comprises placing leads on the electrical component in contact with the printed solder paste features.

17. A method, comprising:
printing a solder paste alignment mark on a printed circuit; and
mounting an electrical component on the printed circuit board using the solder paste alignment mark.

18. The method defined in claim 17 wherein printing the solder paste alignment mark comprises printing the solder paste alignment mark by printing solder paste onto the printed circuit through a stencil in solder paste printing equipment, the method further comprising:
with a camera, gathering information on where the printed circuit is located; and
using the gathered information on where the printed circuit is located when printing the solder paste alignment mark.

19. The method defined in claim 18 further comprising printing solder paste features on the printed circuit when printing the solder paste alignment mark, wherein mounting the electrical component comprises gathering information on wherein the solder paste features are located on the printed circuit by capturing digital image data of the solder paste alignment mark.

20. The method defined in claim 19 wherein the printed circuit comprises metal traces and wherein mounting the electrical component on the printed circuit board comprises:
using a component mounting tool to mount the electrical component so that leads on the electrical component are connected to the metal traces through the solder paste features.
